(19) United States
(12) Patent Application Publication
(10) Pub. No.: US 2023/0216444 A1
(43) Pub. Date: Jul. 6, 2023

(54) BASE TROUGH FOR A THERMAL MODULE, THERMAL MODULE COMPRISING SUCH BASE TROUGH, A SYSTEM FOR EXTRACTING THERMAL ENERGY AND THE USE OF SUCH BASE TROUGH FOR EXTRACTING THERMAL ENERGY FROM SUNLIGHT

(71) Applicant: LOGIC IP AG, Zug (CH)

(72) Inventor: Heiko SCHWERTNER, Ebikon (CH)

(21) Appl. No.: 18/001,153

(22) PCT Filed: Jun. 9, 2020
(86) PCT No.: PCT/EP2020/065908

§ 371 Date: Dec. 8, 2022

(51) Int. Cl. H02S 40/44; F24S 10/55; G05D 7/06

(52) U.S. Cl. CPC H02S 40/44; F24S 10/55; G05D 7/0641

(57) ABSTRACT

The invention relates to a base trough (4) for a thermal module (1), thermal module (1) comprising such base trough (4), a system for extracting thermal energy and the use of such base trough (4) for extracting thermal energy from sunlight.

The invention relates to the technical field of thermal modules. More precisely, the invention relates to a base trough for a thermal module, thermal module comprising such base trough, a system for extracting thermal energy and the use of such base trough for extracting thermal energy from sunlight.

Thermal modules, such as solar collectors, are used to an ever-increasing extent for the purpose of domestic hot water heating or space heating, which is justified both by increasing environmental awareness and by economic considerations.

Solar thermal systems have at least a solar collector and a water storage tank in which, for example, water to be heated for domestic purposes is stored. The solar collector may be connected to a heat exchanger arranged in or on the water storage tank via a heating circuit in which a circulation pump is arranged, which transports the heating medium heated by the solar collector into the heat exchanger of the water storage tank.

The individual thermal modules generally have a flow path including a heat exchanger portion which might be an internal circuit or might be connected to adjacent thermal modules to form a part of a lager heat exchanger medium circuit. Various geometries and arrangements of thermal module flow paths have been described in the art. They tend to suffer from problems associated with inefficient heat exchanging performance, poor homogeneity of the flow, risk of turbulent flow distortions and bubble formation. This holds true, in particular, for cases where pump systems are to be used where flow of the heat exchanger medium is at least partially driven or supported by gravity. Hence, there remains a need in the art for thermal module components which optimize the flow path of the heat exchanger medium within an individual module, to make it more efficient, more even and more controlled

It is therefore am objective of the present invention to overcome the disadvantages in the state of the art. In particular, it is an objective to provide thermal module components which optimize the flow path of the heat exchanger medium within an individual module, to make it more efficient, more even and more controlled or controllable.

The objective is achieve by a base trough for a thermal module, thermal module comprising such base trough, a system for extracting thermal energy and the use of such base trough for extracting thermal energy from sunlight, having the features of the independent claims.

One aspect of the invention relates to a base trough for a thermal module, configured to be covered by a radiation absorber plate or by the outermost layer of a photovoltaic (PV) cell arrangement, the said layer facing away from the sun,

to form a heat exchanger portion of a flow channel adjacent, preferably immediately adjacent, to the radiation absorber plate or to the outermost layer of the PV cell arrangement, for a heat exchanger medium to flow through, preferably a heat extraction medium to flow through;
wherein the base trough comprises
a plurality of wall portions for contacting the said radiation absorber plate or the said outermost layer of the PV cell arrangement in a fluid-tight manner;
a recess for forming a heat exchanger portion of the flow channel;
a recess or tube for forming a feeding channel;
a recess or tube for forming an outlet channel;
   wherein the recess for the heat exchanger portion of the flow channel has at least an open inlet which communicates with the feeding channel and at least an open outlet which communicate with the collecting channel,
   wherein the feeding channel and the collecting channel extend along opposed heads of the base trough, and
   wherein the mean depth of the heat exchanger portion of the fluid channel is smaller than the mean diameter of a cross-section through the feeding channel and smaller than the mean diameter of a cross-section through the collecting channel by at least a factor 1.2, preferably by a factor 1.5 to 15, more preferably by a factor 2 to 10.

In its broadest sense, the base trough for a thermal module, when assembled as intended, is suitable for heating and cooling purposes, in particular for heating and cooling constructions, such as buildings (interior or exterior structures) or walkways. However, the base trough for a thermal module is particularly suitable for extracting thermal energy. The expression “extraction of thermal energy” relates to both heat collection and cooling of excessively heated elements. The object of the extraction of thermal energy can be to collect and utilize heat e.g. for domestic heating purposes. However, the object of the energy extraction can also be to cool certain areas, e.g. portions which tend to overheat such as the surface of solar panels. Ideally, both purposes are achieved at the same time, e.g. in the case of hybrid photovoltaic-thermal systems (PVTsystems). If required, e.g. under certain meteorological conditions, the thermal module can be operated even in reverse to heat the thermal plate or the PV-cell arrangement.

By the term “immediately adjacent to the radiation absorber plate or to the outermost layer of the PV cell arrangement” is meant that the heat exchanger medium flowing through the heat exchanger portion is allowed to substantially completely wet the surface of the radiation absorber plate/the outermost layer of the PV cell arrangement, which cover the base trough and are hence directed towards the flow channel.

By the term “outermost layer of the PV cell arrangement” is meant the external layer of a PV cell arrangement facing away from the sun which is necessarily included in the structure of a PV cell and is electrically insulating, in particular the encapsulant module or the back sheet covering the encapsulant module. Typically the outermost layer of the PV cell arrangement is a back sheet covering an ethylene vinyl acetate (EVA) encapsulant module. Such a back sheet may be made of polymeric material such as a polymeric film, metal such as aluminum, or glass.

By the term “radiation absorber plate” is meant a plate absorbing electromagnetic radiation of the wavelength of a range from 100 nm to 1 mm, in particular light of the visible spectrum and/or infrared radiation, and having a high thermal conductivity of at least 80 W/(m·K), preferably a thermal conductivity between 150 to 450 W/(m·K). Typically, a non-reflecting metal plate is used.

By the expression “the collecting channels extend along opposed heads of the base trough” is meant that the heat exchanger fluid is supplied to the heat exchanger portion from one head of the base trough to the opposite head of the base trough. If the base trough has a substantially rectangular shape, which is preferred, the heads are located at opposing edges of the said rectangle. It is particularly preferred that the feeding channel conveys the heat exchanger medium to the heat exchanger portion substantially at right angles and/or that the collecting channel leads away the medium substantially at right angles from the heat exchanger section. However, the skilled person will appreciate that other angles are also within the scope of the invention.

By the term “depth of the heat exchanger portion of the fluid channel” is meant the dimension of the channel extending away from the radiation absorber plate or the PV cell arrangement. In its simplest form, the heat exchanger portion is a cuboid void enclosed between the recess for forming the heat exchanger portion of the flow channel and the cover (thermal plate or PV-cell arrangement) to be mounted. In this case, the depth would be constant over the entire void. However, other geometries are also possible. For example, the mean depth can be between 2 and 18 mm, preferably between 5 and 15 mm, more preferably between 6 and 12 mm. By “mean” is meant the arithmetic mean.

By “mean diameter of a cross-section through the feeding channel” and “mean diameter of a cross-section through the collecting channel” is meant a diameter of such a channel with the said channel being substantially tubular or having a substantially U-shaped cross section, such that the diameter is constant over the length of the feeding channel/the collecting channel. It is preferred that the feeding and the collecting channel have a constant circular cross section, for example a circular cross section with diameter of 5 to 25 mm, preferably 6 to 23 mm, even more preferably 10 to 20 mm.

The invention is based on the idea that optimized pressure and flow conditions can be achieved by providing
a ratio of the feeding channel's diameter to the mean depth of the heat exchanger portion; and/or
a ratio of the collecting channel's diameter to the mean depth of the heat exchanger portion
   which is ≥1.2. The optimized ratio depends, among other factors, on the density of the heat exchanger fluid. The denser the heat exchanger fluid is, the smaller will be chosen the ratio between the feeding channel's and/or collecting channel's diameter on the one hand and the mean depth of the heat exchanger portion of the fluid channel on the other hand.

In a preferred embodiment, the base trough for a thermal module as described above has an open inlet of the heat exchanger portion of the flow channel which is provided as a longitudinal slid in the feeding channel and/or has an open outlet of the heat ex-changer portion of the flow channel which is provided as a longitudinal slid in the collecting channel. An open arrangement of channels without any unnecessary valves or membranes enables simple manufacturing of the module and still excellent control of the flow due to the optimized geometries of the different flow path sections.

It is preferred that the longitudinal slid has a breadth substantially corresponding to the depth of the heat exchanger portion. By “breadth of the slid” is meant its extension away from the absorber plate/the PV cell arrangement and perpendicular to the flow direction of the heat exchanger medium. Adapting the slid to the cross section of the heat exchanger portion reduces undesirable turbulences in the flow of the heat exchanger medium.

In a preferred embodiment, the base through is such that the longitudinal slid(s) in the feeding channel and/or the collecting channel extend over the full breadth of the heat exchanger portion of the flow channel. By the term “breadth of the heat exchanger portion” is meant its extension perpendicular to the flow direction of the heat extension medium and perpendicular to its depth. By the term “length of the heat exchanger portion” is meant its extension along the flow direction of the heat exchanger medium. If the longitudinal slid(s) in the feeding channel and/or the collecting channel extend over the full breadth of the heat exchanger portion of the flow channel, dead volumes within the heat exchanger portion having a reduced flow rate of heat exchanger medium can be avoided or at least minimized.

One aspect of the invention relates to a base trough for a thermal module as described above, wherein the heat exchanger portion of the flow channel has a plurality of grooves for the heat exchanger medium to flow through, wherein the grooves
are arranged in parallel to each other; and
are arranged such that neighboring grooves are separated from one another in a longitudinal direction by elongated protrusions.

In such an embodiment, a geometry is provided which further optimizes pressure and flow conditions by providing capillary-like substructures within the heat exchanger portion. At the same time, high efficiency of the heat exchange is achieved by allowing the heat exchanger medium to wet the surface of the radiation absorber or the outermost layer of a PV cell arrangement which is directed towards the flow channel to a high extent.

It is particularly preferred that, in the case of a plurality of grooves, the cross-section through an individual groove is substantially V-shaped, substantially U-shaped or has the shape of a semi-ellipse opening towards the radiation absorber/outermost layer of a PV cell arrangement. Heat exchanging capacity and homogeneous laminar flow are thus further optimized.

A preferred embodiment of the invention relates to a base trough for a thermal module as described above, wherein the mean cross section area of the feeding channel is 2 to 10, preferably 3 to 5 times larger than the cross section area of an individual groove; and/or wherein the mean cross section area of the collecting channel is 2 to 10, preferably 3 to 5 times larger than the cross section area of an individual groove. Good results have been achieved with individual grooves having semi-elliptic cross-sections areas of 50 to 80 mm2, preferably 60 to 70 mm2.

These can be combined, for example, with feeding channel/collecting channel cross-section areas of 210 to 270 mm2, preferably 225 to 255 mm2. Such dimensions have proven particularly suitable for a aqueous heat exchanger medium comprising salts and glycol.

In a preferred embodiment, the grooves and the elongated protrusions are uniformly shaped to give a heat exchange portion having an evenly corrugated surface. However, cut-outs or height variations along the elongated protrusions are possible and might be even preferred in order to ensure appropriate mixing of the heat exchanger medium. If there are cut-outs or height variations provided along the elongated protrusions, it is preferably done so in a regular pattern across the heat exchanger portion.

One aspect of the invention relates to a base trough for a thermal module as described above, wherein the elongated protrusions of the heat exchanger portion, when assembled as intended, are spaced apart from the radiation absorber plate or by the outermost layer of a photovoltaic cell arrangement, such that the heat exchanger medium is allowed to pass from one groove to the other over an elongated protrusion and to substantially completely wet the surface of the radiation absorber or outermost layer of a PV cell arrangement which is directed towards the flow channel. In this case, efficiency of the heat exchange is maximized, because the base trough, when assembled as intended, allows the heat exchanger medium to substantially completely wet the surface of the radiation absorber or the outermost layer of a PV cell arrangement which is directed towards the flow channel. The separation of the radiation absorber plate or by the outermost layer of a photovoltaic cell arrangement on the one hand and the elongated protrusions on the other hand may be ensured by appropriate configuration of the plurality of wall portions for contacting the said radiation absorber plate or the said outermost layer of the PV cell arrangement in a fluid-tight manner. The plurality of wall portions may have supports, individual posts or lateral or circumferential shoulder sections where the said radiation absorber plate or the said outermost layer of the PV cell arrangement rests in an assembled state.

In a preferred embodiment, the individual grooves of a base trough for a thermal module as described above have a width of 1 to 20 mm, preferably 5 to 15 mm, the width being the distance between a deepest point of a first groove and the closest deepest point of a neighboring groove. By “deepest” is meant having the largest distance from the radiation absorber plate or the outermost layer of the PV cell arrangement, when assembled for use as intended.

In a preferred embodiment, the elongated protrusions of a base trough for a thermal module as described above have a height in the range of 1 to 20 mm, preferably 5 to 15 mm, wherein the height is the distance between a deepest point of a first groove and the closest point on an edge of an elongated protrusion which points towards the flow channel.

It is preferred that the edge of an elongated protrusion in a base trough as described above which points towards the flow channel and separates a groove from a neighboring groove is spaced apart from the radiation absorber plate or from the outermost layer of a photovoltaic (PV) cell arrangement by 0.1 to 15 mm, preferably by 0.5 to 10 mm, more preferably by 1 to 5 mm. This distance is optimized in view of the pressure conditions and reduction of bubble formation. As a general rule, if only very small separation distances between the shallow sections of the heat exchanger portion (i.e. edges of elongated protrusions) and the cover are chosen, flow resistance increases, so that a powerful circulating pump must be used.

If the transfer fluid is run by gravity or mostly by gravity, the grooves must have small cross-sections such that the static pressure first fills the feeding channels and then the grooves. The order of flow path filling must be observed and controlled in order to avoid formation of dead volume or stagnant fluid within the system.

The base trough for a thermal module as described above may be made of a material selected from the group of
ceramics, in particular clay, terra cotta, zeolite, glass, and
polymers, in particular PP, PET, PA, ABS, PEEK, PC, PMMA;
biomaterials, in particular wood, lignin, wool;
metals, such as aluminum or copper;
or combinations thereof.

Particularly preferred is clay, a natural material which has excellent impacts on room climate in case the thermal module is used for the tiling of building components. Also preferred are polymeric materials which may be made of recycled materials and are particularly sustainable.

By the term “made of” is meant that the base trough comprises such materials. However, it is particularly preferred if the base trough, including plurality of wall portions, the heat exchanger portion, the feeding channel and the collecting channel are formed of one piece, in particular as a result of an applied pressure or an injection molding process, a casting process, a deep drawing process or additive manufacturing/3D-printing. If the element is made of one piece it may fully consist of one of the above listed materials or a blend thereof.

One aspect of the invention relates to a thermal module comprising a base trough according to one of the proceeding claims and a radiation absorber plate or a photovoltaic (PV) cell arrangement, wherein the radiation absorber plate or the PV cell arrangement is fixed on the plurality of wall portions of the base trough by means of adhesive bonding or mechanical fastening means. Simplicity and scalability of the manufacturing process is one of the objectives of the present invention. In its simplest configuration, the thermal module may be composed of only three elements: The base trough, the radiation absorber plate or PV cell arrangement, and the fixation means. As has been described above, the base trough is preferably configured to receive an energy absorbing/generating plate having standard dimensions. For example, the plurality of wall portions may have supports, individual posts or lateral or circumferential shoulder sections where the said radiation absorber plate or the said outermost layer of the PV cell arrangement can be adhesively bonded or mechanically fastened.

Additional stability can be provided if the thermal module as described above is framed, e.g. by a metal frame, in particular an aluminum frame. The thermal module can additionally or alternatively be provided within a housing.

It is particularly preferred that the thermal module is a photovoltaic-thermal (PVT) module and adapted to generate electric energy. The thermal module as described above has excellent heat exchanger performance due to the heat exchanger medium flowing preferably immediately adjacent to the outermost layer of the photovoltaic cell. The thermal module is therefore particularly suitable for efficiently cooling the PV cell arrangement which is otherwise prone to overheat when exposed to intense sunlight. The heat converted by the solar thermal module can be used directly to heat the building or domestic water. The acquisition costs for photovoltaic systems can be redeemed in a significantly shorter time by using hybrid collectors for lost heat recuperation.

In a preferred embodiment, the base trough for a thermal module according as described above is configured such that the feeding channel and collecting channel each have an inlet port and an outlet port for connecting the feeding channel and the collecting channel to the inlet ports and outlet ports of one or more neighboring thermal modules. By way of this configuration, the thermal modules may be connected to neighboring modules in parallel and/or in series. Such connection may be provided by connecting the connecting tube outlet of an upstream module to the connecting tube inlet of a downstream module or the connecting tube inlet of a first module to a connecting tube inlet of a parallel module. More specifically, the thermal module may comprise a connecting tube inlet and a connecting tube outlet adapted such that the modules can be brought into fluidic communication with each other by connecting the connecting tube inlet or outlet of at first module to a connecting pipe inlet of at least a second module, to form a serial and/or parallel arrangement of modules.

It is preferred that the base trough as described above has a plurality of fastening recesses and/or protrusions for mounting the module on a surface, in particular on a roof or a wall of a building. In this case, the base trough may be directly mounted to the roof or the wall, further reducing the construction's components. Suitable fastening means include
pins, rails, screws, bolts, nails clips etc. for inserting into holes, grooves, sockets, etc;
holes, grooves, sockets, etc for receiving pins, rails, screws, bolts, nails clips etc.

Alternatives to the above listed are well known in the art and encompassed by the disclosure. It is particularly preferred that so called “double Christmas tree connectors” are used which allow for reliable fixture within two potentially brittle materials.

One aspect of the invention relates to the use of a trough according as described above for extracting energy from sunlight. The energy can be extracted by means of a thermic absorption or by means electronic power generated by a PV cell assembly, preferably by a combination of both.

One aspect of the invention relates to a system for extracting thermal energy, in particular extracting thermal energy from sunlight, having a plurality of thermal modules as described above and connected to each other.

In particular, the invention relates to a system for extracting thermal energy, in particular extracting thermal energy from sunlight, having
a plurality of thermal modules according to any one of claim 10 or 11, wherein each module has a housing comprising
   a flow adjustment actuator, in particular a pump and/or a valve, for transporting and/or controlling the flow of the heat exchanger medium through the at least one flow channel; and
   a receiver connected to the flow adjustment actuator for receiving an output signal of at least one controller;
at least one controller for controlling the flow control actuators in the plurality of thermal modules; and
optionally, at least one sensor for measuring a parameter selected from the group of temperature, pressure, flow rate and light;
wherein the at least one controller is adapted to individually regulate the flow adjustment actuators of the plurality of modules depending on
data stored in a memory unit connected to the controller; and/or
one or more signal(s) received from the at least one sensor.

The thermal module according to the invention has the advantage that each thermal module has its own flow adjustment actuator(s) and its own receiver(s) pertaining to the actuator. Due to these features, each module can individually adjust its conveying capacity, in particular by regulating the pump frequency and/or the valve position. Hence each module can be most efficiently adjusted to the specific needs given by its particular position on the building, such as height, orientation, north-south exposure, and or changing factors, such as solar altitudes, seasons and daytimes.

For this purpose, the at least one controller may control the flow control actuators based on data which has been stored previously in a memory unit by a user or which is automatically added based on astronomic, climatic or meteorological predictions. Alternatively, the at least one controller may control the flow control actuators based on data that is received as a signal from the at least one sensor. A combination of given and measured data is also possible.

The at least one sensor is for measuring a parameter selected from the group of temperature, pressure, flow rate and light.

However, there are also multi-sensors which are able to sense different parameters at a time. The use of multi-sensors is part of the scope of the invention.

Possible configurations of the system having at least one sensor include a remote sensor which detects at least one parameter, for example the ambient temperature under the roof of a building. Such a parameter may than be processed by a single controller to give individual instructions, which are to be directed to the receivers of the plurality of modules. Such a system would be a system without feedback loop. Typically, a system could be based on at least one ambient sensor for measuring an external ambient temperature and/or for measuring an external ambient light. In this case, the controller could be adapted to control the flow adjustment actuators depending on the signal received from a few ambient sensors.

However, the skilled person will be aware, that it is possible and even preferred to have a closed loop system instead or in addition. For example, a sensor for detecting a temperature of a heat exchanger medium as it leaves the system of thermal modules according the invention, could provide feedback data to the at least one controller on whether or not pump frequencies should be raised or lowered.

It goes without saying that the controller may be either a central controller configured to send a plurality of individualized output signals to the plurality of receivers connected to the flow adjustment actuators of the system, or that there might be several controllers in use for different clusters of modules (roof tile module cluster, wall tile module cluster, etc.). It might be even preferable, that every thermal module has its own controller.

In most cases, a central circulation pump will be installed in the building. The central circulation pump may support the work done by a pump of each module and/or will (co-)determine the flow capacity regulated by the valves. The skilled person will appreciate, that one circuit arrangements as well as multiple circuit arrangements are both encompassed by the scope of the present disclosure. In the case of multiple circuit arrangements, at least two circuits share a common heat exchanger portion. For example, a main circuit actuated by a central circulation pump may share n heat exchanger portions with n individual thermal modules, to accumulate heat.

Suitable heat exchanger media include water, air, a combination of water and air, nanofluids, thermic fluids, phase change materials (PCM), water enriched with mineral salts or brine.

It is another advantage of the system for extracting thermal energy, that the individual regulation of a flow adjustment actuator per thermal module facilitates cleaning and maintenance of the modules. Modules can be rinsed individually at suitable pressures. Clean modules further support high efficiency of the energy harvesting and extend the service life of the system. For a hybrid photovoltaic-thermal system (PVT-systems), life spam can be extended up to 50%.

It is preferred that the system comprises at least two sensors configured for measuring a parameter selected from the group of temperature, pressure, flow rate and light (intensity and/or wave length); wherein the at least one controller is adapted to periodically receive at least two input signals from the at least two sensors and to individually regulate the flow adjustment actuators of the plurality of modules depending on the at least two signals received from the at least two sensors.

If the system comprises at least two sensors configured for measuring a parameter selected from the group of temperature, pressure, flow rate and light, the flow adjustment actuators of at least two modules, or of at least two clusters of modules can be controlled individually, based on changing parameters. By the term “a cluster of modules” is meant a part of the system comprising a sub-group of modules wherein these modules have in common a similar position on the building. For example, the modules of one cluster may share the same mounting height on the building, the same tilt (saddle roof, flat roof or wall), the same north-south exposure and/or the same location in the shade of a neighboring object. In this context, it is appropriate that the at least two sensors measure parameters of the same type (at least two temperatures, at least to pressures) in order to allow a comparison to be made by the controller(s). It goes without saying, though, that at least two sensors of one kind may be combined with at least two sensors of another kind, e.g. at least two flow rate sensors and at least two temperature sensors may be combined.

It is an advantage of this embodiment of the invention that due to the multiplicity of sensors, the flow adjustment actuators of single thermal modules or of clusters consisting of positionally related thermal modules can be controlled according to their specific needs. This improves the overall efficiency of the system. Overheating of surfaces can be avoided, but also the inefficient circulation of insufficiently heated heat extraction medium can be avoided.

In one embodiment of the system, at least one sensor is comprised in each module and is for measuring a parameter of the heat exchanger medium, in particular a temperature, a pressure and/or a flow rate. In an embodiment, a controller is also comprised in each module and is configured for controlling the flow control actuator(s) of the said module.

These embodiments allow the highest extent of individualized operation of the flow adjustment actuators. Also, such a system can be built with highly standardized modules. The system can be particularly easily mounted, and single modules can be replaced in a simple and little error prone fashion.

Another aspect of the invention relates to a system, wherein the at least one controller is adapted to regulate the flow adjustment actuators of the plurality of modules such that a parameter remains within predetermined boundaries.

This system is the system of choice in closed-loop configured systems, when it is desirable to maintain a constant temperature, pressure or flow rate throughout the system or throughout a cluster of modules, measurable at a predefined position within each module. Typical target values include a pressure of no more than 10 bar within the flow channel of a thermal module, or a temperature of no more than 30° C. in proximity of the outlet of the flow channel of a thermal module.

It is preferred that the at least one controller of the system is adapted to regulate the flow adjustment actuators of the plurality of modules such that the pressure of the heat extraction medium in the flow channel remains below 10 bar, preferably between 2-8 bar. This is particularly relevant if the system is a one circuit/larger circuit arrangement. In a one circuit or larger circuit arrangement, i.e. fluidically connecting at least a cluster of individual modules, a central circulation pump will typically move the heat extraction medium from a domestic water processing station to the roof of the building, where it might be temporarily stored and then conveyed further to the plurality of thermal modules.

If the modules are run without any pressure control, this typically results in highly varying pressures within different modules. The pressure depends on how many storeys a building has, on where the temporary storage of heat extraction medium is located, on whether or not the building has a flat or a saddle roof, on the position (height) of each thermal module, e.g. on a facade, and on the initial pressure. For example, in a one circuit solution of a two-storey, saddle roof house with a temporary storage of heat extraction medium at the top of the building, the pressure in the flow channel of a thermal module placed vertically on the wall in proximity of the ground can reach 10 bar and more. Such high pressures require special structural measures and materials, which might drive up the prices per module. However, if a flow adjustment actuator is used and controlled based on a measured pressure, the pressure per module can be individually maintained within reasonable boundaries. Standardized modules can be used and wear of parts is reduced. Suitable sensors are commercially available, for example available from IBA-Sensorik GmbH in Mainhausen, Del. They can, for example, be placed within the flow channel downstream of the flow adjustment actuator and provide a feedback signal to the controller in order to allow the speed or position of the flow adjustment actuator to be shut down if the pressure exceeds a preset value.

In another embodiment of the invention, the at least one controller of the system is adapted to regulate the flow adjustment actuators of the plurality of modules such that the temperature of the extraction medium is between 20 and 30° C., preferably between 23 and 27° C. in a proximity of a flow channel outlet. By the term “flow channel outlet” is meant herein either the position where the heat extraction medium leaves the housing or the position where the heat extraction medium enters a heat exchanger portion of the said module. The former applies in the case of one circuit arrangements or larger circuit arrangements which encompass clusters of modules. The latter is relevant for multiple circuit arrangements. Suitable sensors include e.g. NTC Thermistor Sensors with epoxy resin coatings covering a range of −40 to 125° C., e.g. available with Shenzhen RBD Sensor technology.

In an embodiment of the invention, the at least one controller is adapted to regulate the flow adjustment actuators of the plurality of modules depending on the light intensity measured by the at least two sensors. This embodiment is based on the use of ambient sensors. Ambient light sensors can be mounted on an individual module or can be enclosed in an individual module, e.g. underneath the glass cover of a hybrid PVT-module. Alternatively, or additionally, ambient light sensors can be placed externally to measure a signal for an entire cluster of positionally related modules. Ambient light sensors are suitable to take into account specific weather conditions but also the shadowing situation affecting the modules, e.g. temporary shielding from sunlight by trees. Suitable sensors include a high precision light sensor photoresistor LS06-B3 (spectral response: 450-1050 nm) by Senba.

It is preferred that the system comprises a plurality of sensors for different parameters. For example, a one circuit arrangement in a building may have individual thermal modules, each having a pressure sensor and a temperature sensor and a controller which periodically receives signals from the said pressure sensor and from the said temperature sensor, hence ensuring, by means of appropriately controlling the pumping rate of a pump, that the pressure of the flow extraction medium in the module never exceeds 8 bar and that the temperature of the heat extraction medium at the outlet always reaches 23-27° C.

The combination of photovoltaics with solar thermal energy leads to an improvement in efficiency. In a system as described above, the photovoltaic cell can be electrically connected to the flow control actuator, and optionally to the controller. In this case, the photovoltaic cell supplies the energy-consuming elements of the thermal module with power.

It is preferred that the system is configured such that the flow adjustment actuator is a pump and the pump is operable in reverse. By means of such a system, the thermal modules can be heated. This is useful, particularly in the cold months of a year. The system for converting solar radiation energy into heat can be used to heat a solar panel.

According to this embodiment of the system, the at least one flow channel of the thermal module is fluidically connected (or shares a heat exchanger portion with a circuit that is fluidically connected) to a heat source. The heat source is operated in such a way that the thermal modules of the system are supplied with thermal energy. This means that the individual module and its surroundings can be heated. The combined heat source can consist of a reversibly operated central circulation pump. The heating of the system by reversing the direction of the heat transport can be particularly useful if the photovoltaic modules are covered with snow and/or ice, which considerably decreases the photovoltaic efficiency. With such a weather-related reduction in the efficiency of the photovoltaic module, it can be advantageous for the building's overall energy balance to invest energy for heating the plurality of modules or a cluster of modules for a short period of time. This allows then to generate photovoltaic electricity again over a longer period of time with the snow- and ice-free modules.

It is preferred, that the flow adjustment actuator is a pump because it allows maximum flexibility of mounting the modules not only on tilted roof areas, but also on horizontal flat roofs or on vertical walls. The pump is particularly useful, if the system is configured to be operable in reverse. In an embodiment, the pump is a piezo pump. A piezo pump is small, economic and long-lived. It goes without saying that small pumps may nevertheless be supported by a powerful central circulation pumps.

For operating the pump in reverse, it is particularly preferable that the presence of snow is detected. In the simplest embodiment, the reverse mode can be enabled manually by a user. Alternatively, the switch from forward to reverse mode, or vice versa, can be triggered automatically through the controller based on the signals received from one or a plurality of sensors. In another embodiment, the reverse mode can be turned on based on information retrieved from a third source, mainly the internet.

Generally, the appropriate controlling of the modes, such as forward and the reverse mode respectively, can be supported by artificial intelligence.

The modules of a system as described above may be connected with neighboring modules in parallel and/or in series. Such connection may be provided by connecting the connecting tube outlet of an upstream module to the connecting tube inlet of a downstream module or the connecting tube inlet of a first module to a connecting tube inlet of a parallel module. More specifically, the housing of the thermal module may comprise a connecting tube inlet and a connecting tube outlet adapted such that the modules can be brought into fluidic communication with each other by connecting the connecting tube inlet or outlet of at first module to a connecting pipe inlet of at least a second module, to form a serial and/or parallel arrangement of modules.

In one aspect, the system as described above has modules, wherein the connecting tube inlet and the connecting tube outlet are fluidically connected with each other via the flow channel of the said module. In this case, the tubes and flow channels form an open circuit for the heat extraction medium. In another aspect, though, the system as described above has modules, wherein the flow channel underneath the radiation absorber forms a closed circuit for the heat extraction medium. In this case, the connecting tube inlet and the connecting tube outlet form part of a second, larger circuit encompassing a plurality of heat removal tubes. The heat is removed in in this second, larger circuit of heat removal fluid. In this case, the module comprises a heat exchanger for exchanging heat between a module's closed circuit of heat extraction and the second circuit of heat removal tubes.

In an embodiment, the system as described has a heat exchanger, such that a portion of the at least one flow channel forms one chamber of the heat exchanger and a portion of the heat removal tube forms an adjacent chamber of the heat exchanger. Preferably, a portion of the heat removal tube of the module may form the outer chamber of a heat exchanger pipe and a portion of the at least one flow channel forms the concentrically arranged, inner chamber of the heat exchanger pipe. In this case, the heat exchanger pipe has an inlet for a return line of the at least one flow channel and an outlet for a feed line into the module's at least one flow channel.

One embodiment of the invention relates to a method for exchanging thermal energy, in particular extracting thermal energy, by operating a thermal module according to one of claim 9 or 10, comprising the steps of:

a. heating or cooling a heat exchanger medium in a heat exchanger portion (3) of the flow channel of the thermal module;

b. collecting the heat exchanger medium, from the thermal module for reconditioning.

By the term “reconditioning” is meant that in the case, where a heat extraction medium has been used for extracting thermal energy, such medium is cooled, either as an end in itself or the thermal energy is utilized further. In the case, where a heating medium has been used for heating the thermal module, such medium is reconditioned by supplying energy, for example in a central heating unit.

It is particularly preferred that the method is for extracting thermal energy by operating a system of thermal modules as described above, wherein a plurality of thermal modules as described above are connected in series or in parallel. It is an advantage of the above disclosed thermal modules that they can be operated in both directions. For example, if the thermal modules are mounted on a wall or saddle roof of a house, they can be operated from bottom to top or from top to bottom or—in case of a horizontal arrangement, in both directions. The mode of operation is independent of the position and orientation of the individual thermal module.

In one embodiment, the method for operating a system for extracting thermal energy, in particular extracting thermal energy from sunlight, comprises the steps of:
a. heating or cooling a heat exchanger medium in a plurality of heat exchanger portions disposed within a plurality of thermal modules as described above, wherein the heat exchanger portions are arranged adjacent, preferably immediately adjacent, to radiation absorbers of the modules;
b. adjusting the flow of the heat extraction medium in the flow channels of the modules, by means of at least one flow adjustment actuator per module, in particular a pump and/or a valve;
c. measuring a parameter selected from the group of temperature, pressure, flow rate and light, in particular a temperature, a pressure and/or a flow rate of the heat extraction medium;
d. controlling the at least one flow adjustment actuator per module with at least one controller based on the parameter;
e. removing or inducing heat by collecting the heat exchanger medium, and/or by collecting a heat exchanger fluid which has been in thermic exchange with the heat exchanger medium, from the individual modules.

It is an advantage of this method, that the modules can be adjusted individually depending on their geometric orientation, the (north-south) exposure, their position on the building and/or depending on changing solar altitudes, seasons and daytimes. The over all energy balance of the building can be improved considerably due to such finely adjustable method of operating individual modules or clustered modules of the system. Due to the flow adjustment actuator which is present in the plurality of modules, highly standardized modules can be used. Mounting and replacing becomes easier and more error-resistant.

It is particularly preferred that the parameter is a temperature, a pressure and/or a flow rate of the heat exchanger medium and that the controller is controlled such that, e.g. for the individual module, a parameter of the heat exchanger medium remains within predetermined boundaries. The use of feedback loops within a thermal module ensures continuous control and of performance and, eventually, optimized energy efficiency.

The method is preferably for operating a system as described earlier and the system may include the listed features. For example, the method may be such that the individual modules are operated in fluidic connection with each other, wherein the modules are connected in parallel and/or in series. The method according to the invention also encompasses a method which comprises an additional step of generating electric energy in photovoltaic cells comprised in the module and, optionally, operating the flow adjustment actuators and/or the controller by electric energy generated in photovoltaic cells comprised in the module.

It is an aspect of the invention that the method comprises the step of reversing the flow direction of the heat extraction medium by reversing the operation mode of the pump, such that the thermal module is heated. In such an embodiment, the flow channels are fluidically connected to a heat source (or are fluidically connected to a heat exchanger portion, which is provided with thermal energy from heat source). As a result of this method, the modules and their immediate surroundings can be heated. Such a configuration is desirable for hybrid PVT modules. As described earlier, this method allows optimized operations in the cold months where the thermal power used for defrosting the thermal panels may be set off by the gain in photovoltaic energy obtained by using the defrosted hybrid photovoltaic-thermal (PVT) modules.

In one aspect of the invention, the method as described above is characterized in that the modules are operated in an open circuit of heat exchanger medium. In such a method, the flow adjustment actuators may be valves and the open circuit may be driven or supported by a central circulation pump. In another aspect of the invention the heat exchanger medium in a module may be operated by a pump in a closed circuit of heat exchanger medium. Preferably, in this case, the heat is transmitted by means of a heat exchanger portion to a heat removal medium contained in a heat removal tube.

In an aspect of the invention, the method comprises the steps of
measuring an external ambient temperature and/or measuring an external ambient light by means of at least two ambient sensors;
controlling the flow adjustment actuators depending on a signal received by the controller from the said at least two ambient sensor.

Such an embodiment is useful if the individual modules or positionally related clusters of modules are to be operated according to specific needs. The at least to sensors in this case provide comparative data for steering the modules of the system or certain clusters of the system, according to the geometric orientation, tilt, north-south exposure of the said portion of the building, as well as changing solar altitudes, seasons and daytimes. For example, by means of a light sensor, coverage of the glass surface of a photovoltaic cell by snow can be detected and a heating mode can be triggered.

The present invention and its advantages will be better understood by referring to the following exemplary description and the drawings which are, however, not meant to limit the scope of the application.

The following figures show:

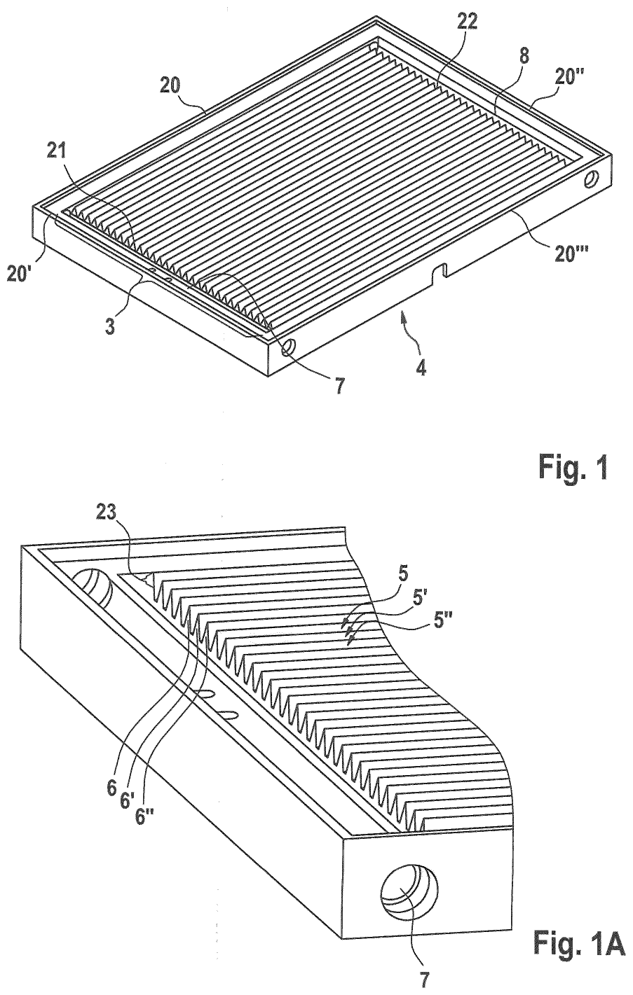

FIG. 1 Perspective view on a base trough according to the invention (from diagonally above);

FIG. 1A Perspective view on a detail of FIG. 1;

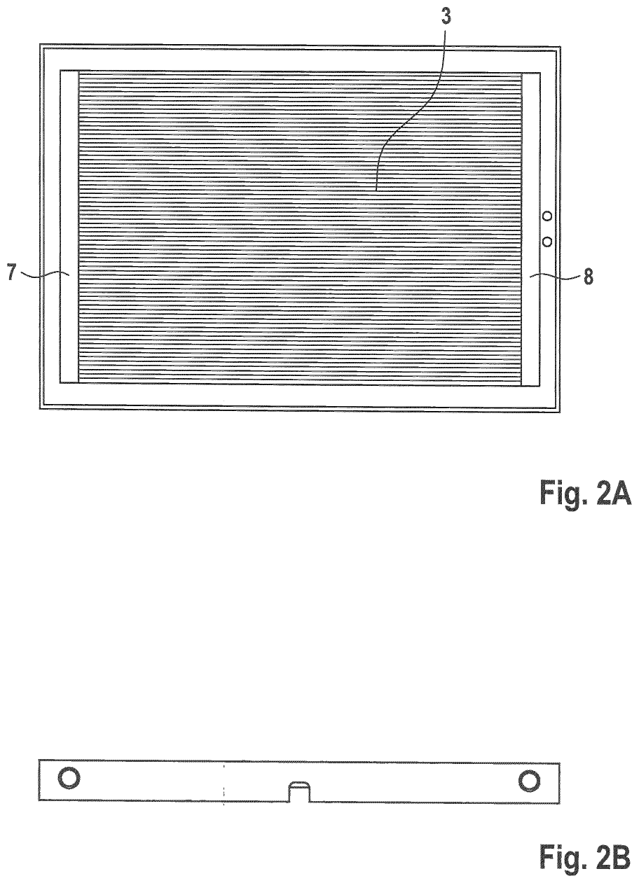

FIG. 2A Top view on a base trough according to the invention;

FIG. 2B Lateral view (side extending along the flow path) on a base trough according to the invention;

FIG. 3 Perspective view on an alternative embodiment of a thermal module;

FIG. 4 Perspective view on a base trough according to the invention (from diagonally below);

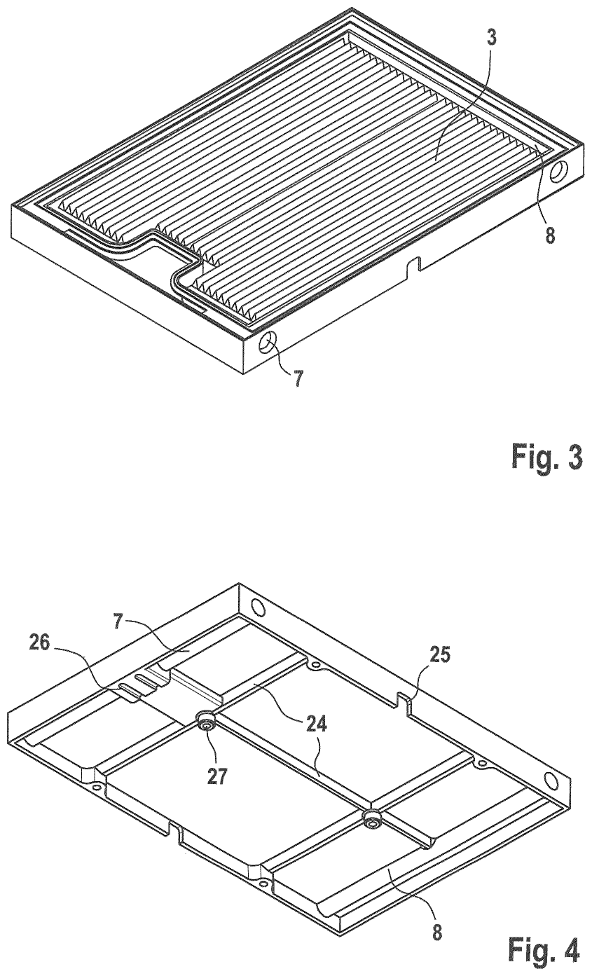

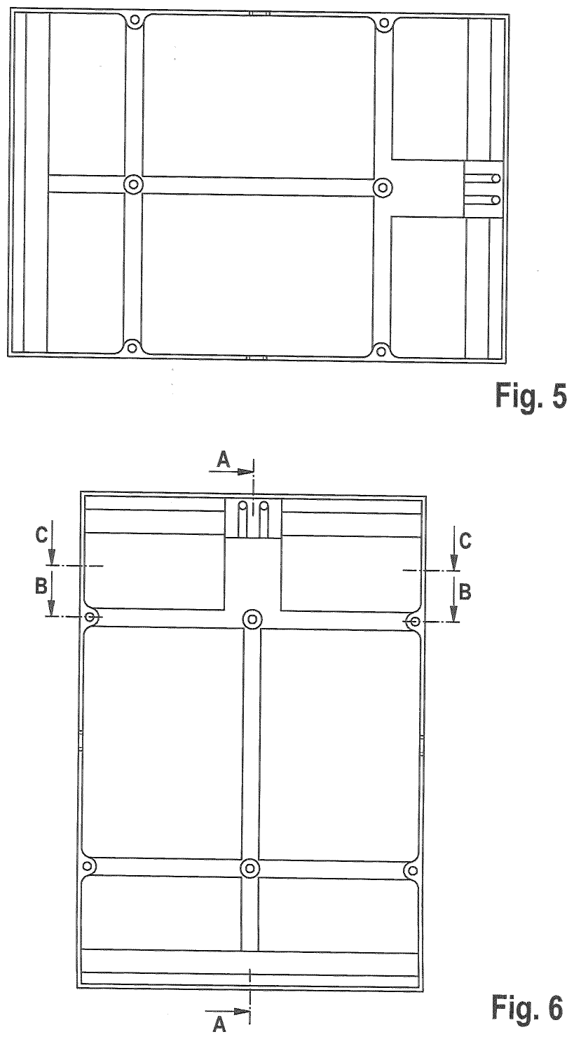

FIG. 5 Bottom view on a base trough according to the invention;

FIG. 6 Bottom view on a base trough according to the invention indicating linear cuts AA, BB and CC;

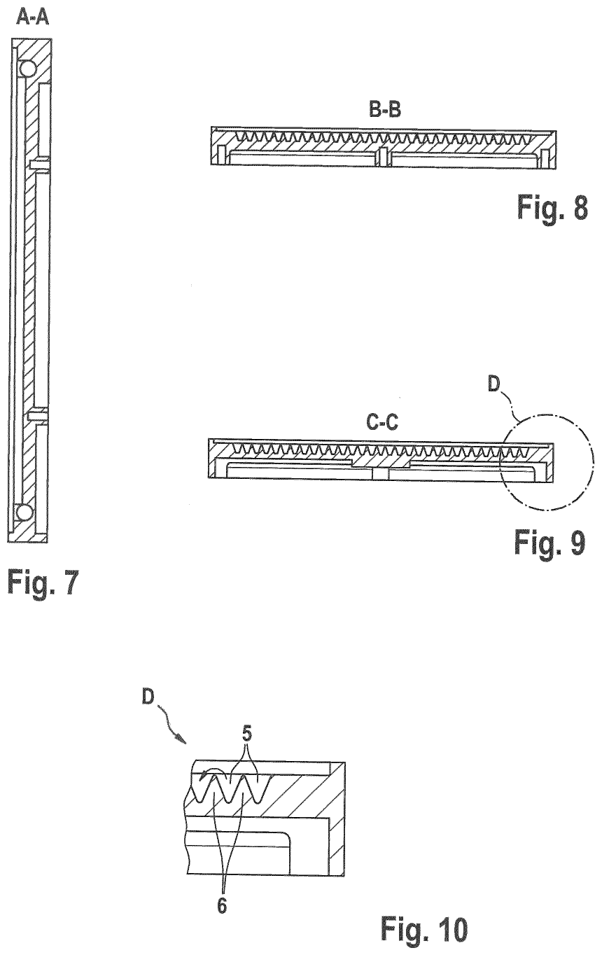

FIG. 7 Cross-section of linear cut AA through the base trough of FIG. 6;

FIG. 8 Cross-section of linear cut BB through the base trough of FIG. 6;

FIG. 9 Cross-section of linear cut CC through the base trough of FIG. 6;

FIG. 10 Enlarged view on detail D of FIG. 9;

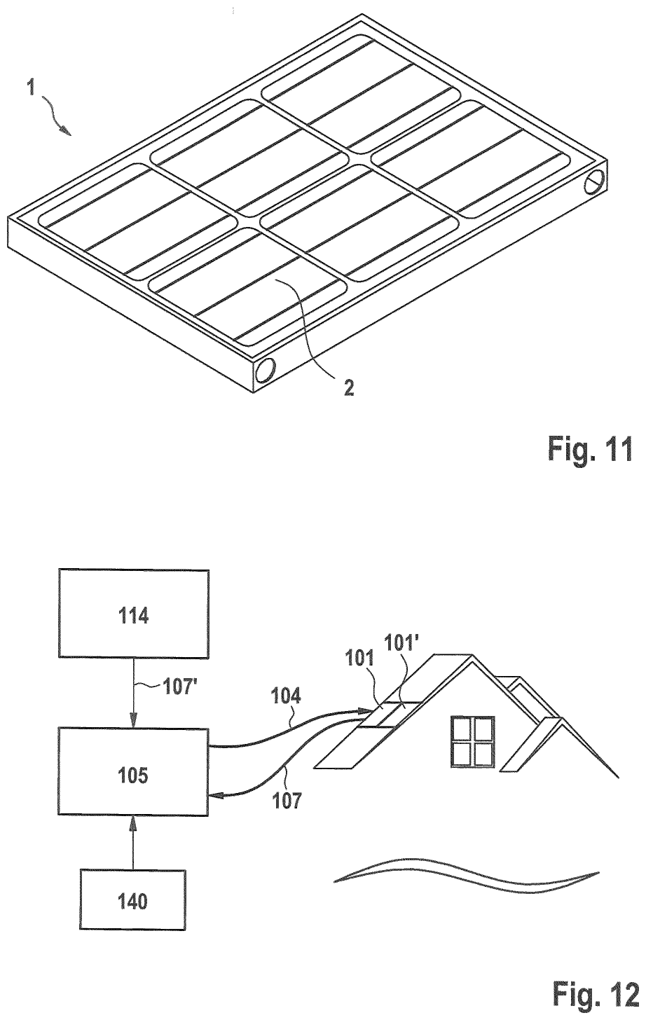

FIG. 11 Perspective view on a thermal module according to the invention, the base trough and a PV cell arrangement being assembled for the intended use;

FIG. 12 Schematic depiction of a system for extracting thermal energy from sunlight.

FIG. 1 shows a perspective view on a base trough according to the invention (from diagonally above). The base trough is for a thermal module and it is configured to be covered by a radiation absorber plate or by the outer-most layer of a photovoltaic (PV) cell arrangement, the said layer facing away from the sun. There is a heat exchanger portion of a flow channel 3 formed, the breadth of which is indicated by the curled bracket. When assembled for the intended use, the absorber plate or PV cell arrangement (not shown) would be lowered onto the heat exchanger portion to seal off the flow channel adjacent, preferably immediately adjacent, to the radiation absorber plate/the outermost layer of the PV cell arrangement, for a heat exchanger medium, preferably a heat extraction medium, to flow through. The base trough 4 comprises a plurality of wall portions 20,20′,20″,20′″ for contacting the said radiation absorber plate or the said outermost layer of the PV cell arrangement in a fluid-tight manner. The trough has a recess for forming a heat exchanger portion of the flow channel 3, a recess or tube for forming a feeding channel 7 and a recess or tube for forming an outlet channel 8. The recess for the heat exchanger portion of the flow channel has an open inlet 21 which communicates with the feeding channel 7 and an open outlet 22 which communicates with the collecting channel 8. The feeding channel and the collecting channel extend along opposed heads of the base trough 4.

As can be seen from the enlarged view of the transition between inlet tube and heat exchanger portion in FIG. 1A, the mean depth 23 of the heat exchanger portion of the fluid channel is smaller than the mean diameter of a cross-section through the feeding channel and also smaller than the mean diameter of a cross-section through the collecting channel by at least a factor 1.2, preferably by a factor 1.5 to 15, more preferably by a factor 2 to 10.

In the shown embodiment, the heat exchanger portion 3 of the flow channel has a plurality of grooves 5,5′,5″ for the heat extraction medium to flow through, wherein the grooves 5,5′,5″ are arranged in parallel to each other; and are arranged such that neighboring grooves are separated from one another in a longitudinal direction by elongated protrusions 6,6′,6″.

FIG. 2A shows a top view on a base trough according to the invention. It can again be seen that the heat exchanger portion 3 has an evenly corrugated surface, in the present case a rectangular plate having around 60 linear grooves extending between the head ends 7 and 8. FIG. 2B shows a lateral view (side extending along the flow path) on a base trough according to the invention. The diameter of the feeding channel's and collecting channel's inlet/outlet have a diameter of 17 mm each in the shown embodiment.

FIG. 3 shows a perspective view on an alternative embodiment of a thermal module, wherein the feeding channel 7 is provided in curved shape in order to accommodate a junction box with a separating diode and cables (MC4-EU standard), which allows to control operation of individual modules of a system independently of each other. As can be seen from the embodiment, the feeding and/or collecting channel(s) 7,8 need not be of a linear shape.

FIG. 4 shows a perspective view on a base trough according to the invention (from diagonally below). The base trough 4 for a thermal module 1 has a plurality of struts 24 for providing stability and fastening recesses 25,26 and/or protrusions 27 for mounting the module on a surface, in particular on a roof or a wall of a building. The same structures for stability and ease of mounting are visible in FIG. 5, which shows a bottom view on a base trough according to the invention.

FIG. 6 again shows a bottom view on a base trough according to the invention indicating linear cuts AA, BB and CC.

FIG. 7 shows a cross-section of linear cut AA through the base trough of FIG. 6. As can be seen from this Figure, the head wall portions have supports shoulder sections where the radiation absorber plate or outermost layer of the PV cell arrangement rests in an assembled state. In the present case, the base trough even includes circumferential shoulder sections such that the rectangular cover is supported on each side.

FIG. 8 shows a cross-section of linear cut BB through the base trough of FIG. 6 and FIG. 9 shows a cross-section of linear cut CC through the base trough of FIG. 6. The lateral shoulder portions as well as the mounting protrusions can be seen from these cross sections. Also, the maximum depth of the heat exchanger portion, which is here indicated as 5 mm, hence more than three times smaller than the feeding channel's and collecting channel's inlet/outlet diameter.

FIG. 10 shows an enlarged view on detail D of FIG. 9. The cross-section through an individual groove has the shape of a semi-ellipse opening towards the position of the absorber plate/the outermost layer of a PV cell arrangement. The curved arrow implies that in some embodiments, the elongated protrusions 6 of the heat exchanger portion may be spaced apart from the radiation absorber plate (not shown) or from the outermost layer of a PV cell arrangement (not shown), such that the heat exchanger medium is allowed to pass from one groove to the other over an elongated protrusion 6 and to substantially completely wet the surface of the radiation absorber or outermost layer of a PV cell arrangement which is directed towards the flow channel.

FIG. 11 shows a perspective view on a thermal module according to the invention, the base trough and a PV cell arrangement being assembled for the intended use. In the shown embodiment, the PV cell arrangement is a 2×3 wafer and may have a total output of 28 W. Typical dimensions of such photovoltaic surface are 520 mm×360 mm. The current produced by the PV-cells may be used to run the energy-consuming elements of the thermal module, e.g. flow adjustment actuators. The panel pf PV cells may be provided under a glass plate in an aluminum frame.

FIG. 12 shows a schematic view of a system for extracting thermal energy from sunlight. The system has a plurality of thermal modules according to the invention, which are located on top of a saddle roof of a building. Each module 101,101′ has a housing. The components comprised in the housing (radiation absorber, at least one flow channel for a heat extraction medium, a flow adjustment actuator, receiver connected to the flow adjustment actuator for receiving an output signal 104 of at least one controller 105, and optionally: at least one sensor) are not shown in FIG. 1. A controller 105 for controlling the flow control actuators in the plurality of solar thermal modules is comprised in the system. The controller 105 receives data, which is stored in a memory unit 140 connected to the controller, and which may consist of, e.g. astronomic, climatic or meteorological data. The controller 105 additionally or alternatively receives one or more signals 107,107′ from at least one sensor. The sensor(s) may be comprised in the housing of a module (not shown) or there may be an ambient sensor(s) 114, purposefully placed to detect a parameter which is relevant for an entire region or cluster of the system. The controller 105 is adapted to individually regulate the flow adjustment actuators of the plurality of modules 101,101′ depending on the data received from the memory unit 140, and/or on the signal(s) 107 received from a sensor comprised in the housing of a module, and/or on the signal(s) 107′ received from an ambient sensor 114. In order to regulate the flow adjustment actuators of the plurality of modules 101,101′, the controller 105 sends out an output signal 104 to the receivers of the modules 101,101′.

1. A base trough for a thermal module, configured to be covered by a radiation absorber plate or by the outermost layer of a photovoltaic (PV) cell arrangement, the said layer facing away from the sun, to form a heat exchanger portion of a flow channel adjacent to the radiation absorber plate or to the outermost layer of the PV cell arrangement, for a heat exchanger medium to flow through;
wherein the base trough comprises
a plurality of wall portions for contacting said radiation absorber plate or said outermost layer of the PV cell arrangement in a fluid-tight manner;
a recess for forming a heat exchanger portion of the flow channel;
a recess or tube for forming a feeding channel;
a recess or tube for forming an outlet channel;
wherein the recess for the heat exchanger portion of the flow channel has at least an open inlet which communicates with the feeding channel and at least an open outlet which communicates with the collecting channel,
wherein the feeding channel and the collecting channel extend along opposed heads of the base trough, and
wherein the mean depth of the heat exchanger portion of the fluid channel is smaller than the mean diameter of a cross-section through the feeding channel and smaller than the mean diameter of a cross-section through the collecting channel by at least a factor of 1.2.

2. The base trough for a thermal module according to claim 1, wherein the heat exchanger portion of the flow channel has a plurality of grooves for the heat exchanger medium to flow through, wherein the grooves
are arranged in parallel to each other; and
are arranged such that neighboring grooves are separated from one another in a longitudinal direction by elongated protrusions.

3. The base trough for a thermal module according to claim 2, wherein the cross-section through an individual groove is substantially V-shaped, substantially U-shaped, or has the shape of a semi-ellipse.

4. The base trough for a thermal module according to claim 2, wherein the mean cross-sectional area of the feeding channel is 2 to 10 times larger than the cross-sectional area of an individual groove; and/or wherein the mean cross-sectional area of the collecting channel is 2 to 10 times larger than the cross-sectional area of an individual groove.

5. The base trough for a thermal module according to claim 2, wherein the elongated protrusions of the heat exchanger portion are spaced apart from the radiation absorber plate or from the outermost layer of a photovoltaic cell arrangement, such that the heat exchanger medium is allowed to pass from one groove to the other over an elongated protrusion and to substantially completely wet the surface of the radiation absorber or outermost layer of a PV cell arrangement which is directed towards the flow channel.

6. The base trough for a thermal module according to claim 2, wherein the edge of an elongated protrusion which points towards the flow channel and separates a groove from a neighboring groove is spaced apart from the radiation absorber plate or from the outermost layer of a photovoltaic cell arrangement by 0.1 to 15 mm, preferably by 0.5 to 10 mm, more preferably by 1 to 5 mm.

7. The base trough for a thermal module according claim 1, wherein the base trough is of a material selected from the group consisting of
ceramics;
polymers;
biomaterials; and
metals;
or a combination thereof.

8. The base trough for a thermal module according to claim 1, wherein the base trough, including the plurality of wall portions, the heat exchanger portion, the feeding channel, and the collecting channel are formed of one piece.

9. A thermal module comprising a base trough according to claim 1 and a radiation absorber plate or a photovoltaic cell arrangement, wherein the radiation absorber plate or the PV cell arrangement is fixed on the plurality of wall portions of the base trough by means of adhesive bonding or mechanical fastening means.

10. The thermal module according to claim 9, wherein the thermal module is a hybrid photovoltaic-thermal module and adapted to generate electric energy.

11. The base trough for a thermal module according to claim 1, wherein the feeding channel and collecting channel each have an inlet port and an outlet port for connecting the feeding channel and the collecting channel to the inlet ports and outlet ports of one or more neighboring thermal modules.

12. The base trough for a thermal module according to claim 1, having a plurality of fastening recesses and/or protrusions for mounting the module on a surface.

13. A method for exchanging thermal energy by operating a thermal module according to claim 9, the method comprising the steps of:
a. heating or cooling a heat exchanger medium in a heat exchanger portion of the flow channel of the thermal module; and
b. collecting the heat exchanger medium; from the thermal module for reconditioning.

14. Use of a base trough according to claim 1 for extracting energy from sunlight.

15. A system for extracting thermal energy, in particular extracting thermal energy from sunlight, the system comprising:
a plurality of thermal modules according to claim 9, wherein each module has a housing comprising
a flow adjustment actuator for transporting and/or controlling the flow of the heat exchanger medium through the at least one flow channel; and
a receiver connected to the flow adjustment actuator for receiving an output signal of at least one controller;
at least one controller for controlling the flow control actuators in the plurality of thermal modules; and
wherein the at least one controller is adapted to individually regulate the flow adjustment actuators of the plurality of modules depending on data stored in a memory unit connected to the controller and/or one or more signal(s) received from the at least one sensor.

16. The system according to claim 15, wherein the flow adjustment actuator is a pump and the pump is operable in reverse such that the thermal module is heated.

17. The base trough for a thermal module as in claim 1 wherein the mean depth of the heat exchanger portion of the fluid channel is smaller than the mean diameter of a cross-section through the feeding channel and smaller than the mean diameter of a cross-section through the collecting channel by a factor of 1.5 to 15.

18. The base trough for a thermal module as in claim 1 wherein the mean depth of the heat exchanger portion of the fluid channel is smaller than the mean diameter of a cross-section through the feeding channel and smaller than the mean diameter of a cross-section through the collecting channel by a factor of 2 to 10.

19. The base trough for a thermal module as in claim 6 wherein the edge of the elongated protrusion is spaced apart from the radiation absorber plate or from the outermost layer of a photovoltaic cell arrangement by 1 to 5 mm.

20. The base trough for a thermal module according to claim 7, wherein the ceramics are selected from the group consisting of clay, terra cotta, zeolite and/or glass, the polymers are selected from the group consisting of PP, PET, PA, ABS, PEEK, PC and/or PMMA, the biomaterials are selected from the group consisting of wood, lignin and/or wool, and the metals are selected from the group consisting of, in particular aluminum and/or copper.
